(19) United States
(12) Patent Application Publication
(10) Pub. No.: US 2002/0153600 A1
(43) Pub. Date: Oct. 24, 2002

(54) Double sided chip package

(75) Inventors: Cecil Chang, Pingduan City (TW); Jansen Chiu, Kaohsiung (TW)

Correspondence Address: DOUGHERTY & TROXELL, 5205 LEESBURG PIKE, SUITE 1404, FALLS CHURCH, VA, 22041, US

(73) Assignee: Walton Advanced Electronics LTD

(21) Appl. No.: 09/837,272

(22) Filed: Apr. 19, 2001

(51) Int. Cl. H01L 23/495

(52) U.S. Cl. 257/676; 257/686; 257/692; 257/723

(57) ABSTRACT

A double sided chip package is disclosed. The package includes a LOC leadframe having a plurality of leads. Each lead is outwardly divided into a supporting portion extended between a bottom chip and a upper chip for supporting both chips, an inner connecting portion sealed by a package body for electrically connecting the bottom chip and the upper chip to the LOC leadframe by wire-bonging, and an outer portion exposed from the package body. So the double sided chip package has the benefits of a less warping, a stronger lead bonding, and a well-balancing molding flow.

### FIELD OF INVENTION

The present invention relates to a double sided chip package, in particular to a double sided chip package with a LOC lead frame.

### DESCRIPTION OF THE PRIOR ART

Common semiconductor devices use thermosetting liquid compound to pack a semiconductor chip, so as to protect the chip from dust and humidity invasion. The I/O connectors of such a chip are extended from the corresponding leads of the lead frame, so as to mount on the surface of the circuit board.

The so-called ‘LOC lead frame’ is the type of ‘Lead-On-Chip’ lead frame for short. That is, the leads of the lead frame are extended on the chip. These leads are electrically connected and adhesively fixed to the chip without using the die pad of the lead frame.

One type of double sided chip package has been claimed in the U.S. Pat. No. 6,118,176. As shown in FIG. 1, such a double sided chip package 10 possesses a LOC lead frame, with its upper chip 11 and bottom chip 12 back-to-back adhesively attached by an adhesive film 14. The leads 13 of the LOC lead frame are extended on the bottom surface of the bottom chip 12 and are fixed by another adhesive film 15, so as to enable the bonding wires 16 to connect the lead 13 and the pads of the bottom chip 12. A circuit board 18 possessing a hole is adhesively attached to the upper surface of the upper chip 11, such that the bonding wires 16 can connect the circuit board 18 and the bonding pads of the upper chip 11 as well as the circuit board 18 and leads 13. A package body 17 is then used to seal the above double sided chip package. The package cost increases because the circuit 18 has to be positioned on the top surface of the upper chip 11 and an indirect and massive wire-bonding process is required (from the upper chip 11 to the circuit board 18, then from the circuit board 18 to the lead 13 of the lead frame). Furthermore, in order to generate a well-balanced molding flow, the lead 13 of the LOC lead frame must be appropriately bent forming a downset area, so that the double sided chip package would need a special shape of LOC lead frame.

### OBJECTS AND DESCRIPTION OF THE INVENTION

The main object of the present invention is to provide a double sided chip package comprising a LOC lead frame as a datum plane and two chips respectively being fixed to be above and beneath the inner ends of the leads, such that the structure can achieve a balanced molding flow without bending the leads and its leads are better stabilized because they are sandwiched by the upper and bottom chips.

The another object of the present invention is to provide a double sided chip package comprising a LOC lead frame as a datum plane and two chips being respectively fixed to be above and beneath the inner ends of the leads. The advantages of such a structure include double capacity of memory, least deformation, less stress, and better protection.

The double sided chip package in the present invention comprises a LOC lead frame, an upper chip, a bottom chip, a plurality of leads and a package body. The LOC lead frame has a plurality of leads and each lead from inside to outside can be divided into a supporting portion, an inner connecting portion and an outer connecting portion. The upper chip possesses a plurality of bonding pads on its upper surface and is fixed upon the supporting portions of the leads with its bottom surface. The bottom chip possesses a plurality of bonding pads on its bottom surface and is fixed beneath the supporting portions of the leads with its top surface. A plurality of bonding wires electrically connect the inner connecting portions of the corresponding leads and the bonding pads of the upper chip and the bottom chip. Moreover, the package body seals the upper chip, the bottom chip, the bonding wires and the supporting portion and inner connecting portion of the leads.

### DETAILED DESCRIPTION OF THE INVENTION

The following embodiments of the present invention will be disclosed (please also refer to the attached drawings)

FIGS. 2 and 3 demonstrate the first embodiment of the present invention, a double sided chip package 20 comprises a LOC lead frame, an upper chip 21, a bottom chip 22 and a package body 27.

As shown in FIGS. 2 and 3, the LOC lead frame in the present invention is a ‘Lead-On-Chip’ type of lead frame. Such a lead frame can be manufactured by applying common stamping or etching technique on a thin metal board made of steel or copper. It possesses a plurality of leads 23, with each lead 23 from inside to outside being divided into a supporting portion 231, an inner connecting portion 232 and an outer connecting portion 233. The supporting portion 231 is sandwiched between the upper chip 21 and the bottom chip 22 and is used to support the same two chips 21 and 22. The inner connecting portion 232 is inside the wire-bonding area 28, and serves as the connections between the bonding wire 26 and the leads 23. The outer connecting portion 233 is outside the encapulating area 29, and serves as the outer electricity terminals for the double sided chip package 20. Since the supporting portion 231 of the lead 23 is inwardly extended to the area between the upper chip 21 and the bottom chip 22, this LOC lead frame can also be regarded as a ‘lead-between-double-chips’ type of lead frame. The leads 23 can support the upper chip 21 and the bottom chip 22 simultaneously and have a better stability as they are sandwiched by the same two chips 21 and 22. Therefore, as shown in FIG. 2, the supporting portions 231 and the inner connecting portions 232 of the leads 23 are formed on the same plane. Such a structure can provide a excellent stability without the needs of bending the leads. The supporting portion 231 and the inner connecting portion 232 is better formed on a plane P1 with equal distance to the upper chip 21 and the bottom chip 22. When injecting molding compound being the precursor of the package body 27 before curing into the 1:1 molds (along the encapulating area 29), such a structure can achieve a well-balanced molding flow without bending the leads 23. After curing, as shown in FIG. 2, the shape of the outer connecting portion 233 of the leads 23 is bend to be gull-like or other shapes (e.g., I-like or J-like) for surface mounting.

The upper chip 21 is fixed to the top of the supporting portions 231 of the aboveleads 23. The bottom surface of the upper chip 21 is adhesively fixed to the supporting portions 231 of the leads 23 with a first adhesive tape 24, which is made of insulating materials like polyimide. The top surface of the upper chip 21 possesses a plurality of bonding pads and integrated circuit elements (not illustrated in the figures). The upper chip 21 can be memory chip like DRAM (Dynamic Random Access Memory), SRAM (Static Random Access Memory) and flash memory, microprocessor, or chip with logic functions. Besides, the electricity connections between the upper chip 21 and the lead frame is achieved by a plurality of bonding wires 26, made of gold or copper, connecting the bonding pads of the upper chip 21 and the inner connecting portion 232 of the corresponding leads 23 of the lead frame by wire-bonding techniques.

The bottom chip 22 can be the same type as the upper chip 21 or any other functional chips. It is fixed to the bottom of the supporting portions 231 of the above-mentioned leads 23. The top surface of the bottom chip 22 is adhesively fixed to the supporting portions 231 of the leads 23 with a second adhesive tape 25, which is made of insulating material like polyimide. The bottom surface of the bottom chip 22 possesses a plurality of bonding pads and integrated circuit elements (not illustrated in figures). The bonding pads of the bottom chip 22 connect to the inner connecting portions 232 of the corresponding leads 23 with a plurality of bonding wires 26 using wire-bonding techniques. Besides, the package body 27 of the double sided chip package 20 seals the upper chip 21, the bottom chip 22, the first adhesive tape 24, the second adhesive tape 25, the bonding wires 26 and the supporting portions 231 and the inner connecting portions 232 of the leads 23 in order to protect the above-mentioned double sided integrated structure. However, the outer connecting portion 233 of the lead 23 is exposed from the package body 27 for electrical connection..

Therefore, the double sided chip package 20 of the present invention is capable of packageing two chips with single lead frame, and further achieves such multiple effects as less warping (no thermal expansion difference between the upper and the bottom part), less stress (the supporting portion of the lead is strip-shaped and can absorb stress), better protection (the upper and the bottom chip are sealed in the package body), more stabilized leads (leads are sandwiched between the upper and bottom chips) and well-balanced molding flow.

FIGS. 4 and 5 illustrate the second embodiment of the present invention. This double sided chip package 30 mainly comprises a LOC lead frame, an upper chip 31, a bottom chip 32 and a package body 37, wherein the upper chip 31, the bottom chip 32 and the package body 37 are respectively the same as the upper chip 21, the bottom chip 22 and the package body 27 in the first embodiment, and will be not discussed repeatedly here.

As shown in FIG. 5, the LOC lead frame is another type of ‘lead-on-chip’ lead frame comprising a plurality of leads 33 and two power leads 35. Every lead 33 is used to transfer signals generated by the upper chip 31 and the bottom chip 32, and can be further from inside to outside divided into a supporting portion 331, an inner connecting portion 332, and an outer connecting portion 333. The supporting portions 331 are sandwiched between the upper chip 31 and the bottom chip 32, and are used to support the same two chips. The inner connecting portions 332 locates in a frame-shape wire-bonding area 38 and serves as the electrical connection sections of the leads 33 for the bonding wires 36. The outer connecting portion 333 locates outside the encapulating area 39 (package body 37) and serves as the outer electrical connector for the double sided chip package 30. The power leads 35 are commonly known as the bus bar because their shape is like a handle. Inside the encapulating area 39, each power lead 35 can be further divided into a supporting portion 351 and an inner connecting portion 352 extending outwardly to the two sides. The supporting portions 351 of the power leads 35 locates among the supporting portion 331 of the other leads 33 and is better to be perpendicular to the supporting portion 331. Likewise, the supporting portion 351 is used to support the upper chip 31 and the bottom chip 32. The inner connecting portions 352 locates inside a frame-shaped wire-bonding area 38, and serves as the interconnections from the bonding wire 36 to the power lead 35, so as to transfer electrical power to the upper chip 21 and the bottom chip 22. With the leads 33 and 35 of the above LOC lead frame in between the two chips, the leads 33 can simultaneously support the upper chip 31 and the bottom chip 32 and because the leads 33 is sandwiched between the same two chips, they therefore have better stability. As shown in FIG. 4, the supporting portions 331 and the inner connecting portions 332 of the leads 33 are formed on the same plane, such that it can achieve better stability without bending. A better situation is where the supporting portion 331 and the inner connecting portion 332 are formed on a plane PI with the same distance to the upper chip 31 and the bottom chip 32. It can achieve well-balanced molding flow without the needs of bending the leads 33.

In this embodiment, the double sided chip package 30 additionally includes a thermosetting, insulating and non-electricity conductive epoxy compound 34. Epoxy compound 34 can be applied to the area between the upper chip 31 and the bottom chip 32 when it is in liquid-glue status. After curing, it can simultaneously fix the upper chip 31, the bottom chip 32 and the lead 33 and 35 of the lead frame. After wire-bonding the wire 36 and molding the package body 37, a double sided chip package 30 with such multiple effects as less warping, less stress, better protection, more stabilized lead and well-balanced molding flow can be obtained.

### DESCRIPTIONS OF THE DRAWINGS

FIG. 1: A cross-sectional view of the structure of the double sided chip package in U.S. Pat. No. 6,118,176;

FIG. 2: A cross-sectional view of the double sided chip package of a first embodiment in the present invention;

FIG. 3: A top view of the double sided chip package of a first embodiment before molding in the present invention;

FIG. 4: A cross-sectional view of the double sided chip package of a second embodiment in the present invention; and

FIG. 5: A top view of the double sided chip package of a second embodiment before molding in the present invention.

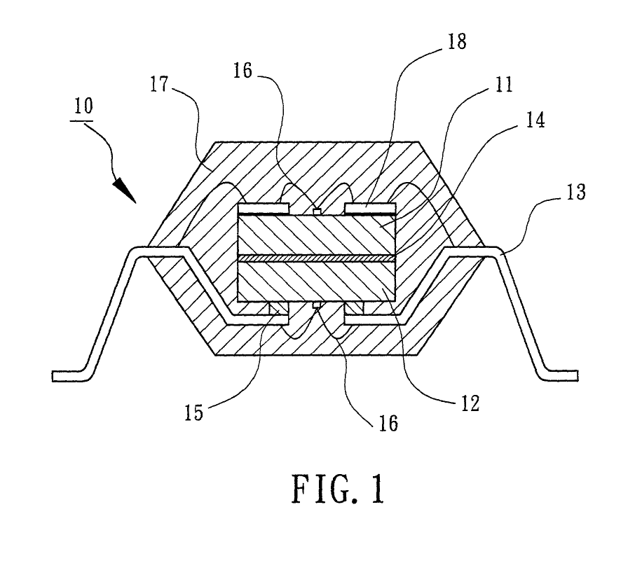

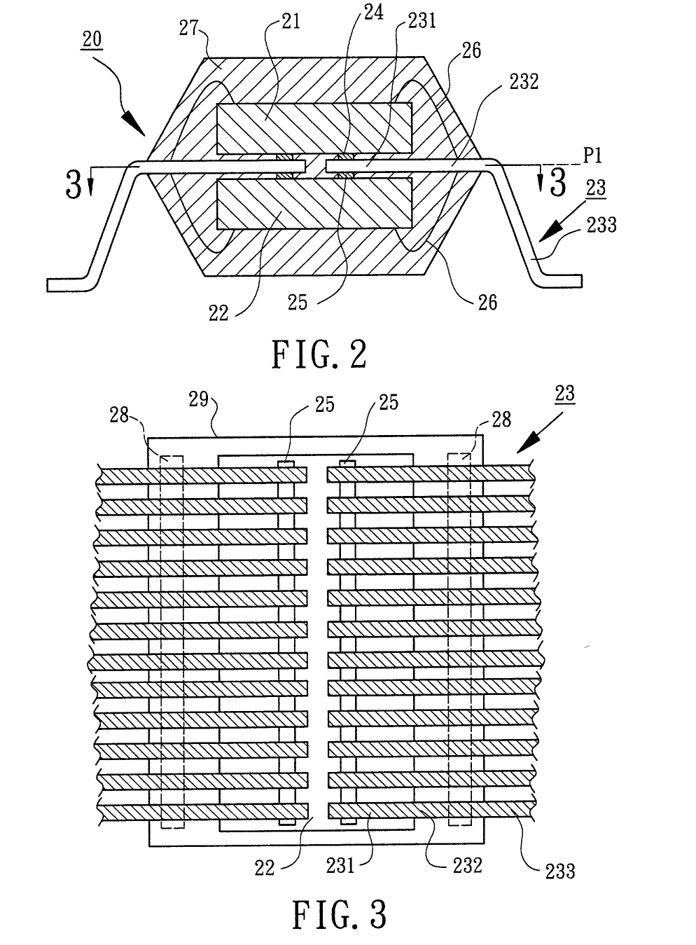

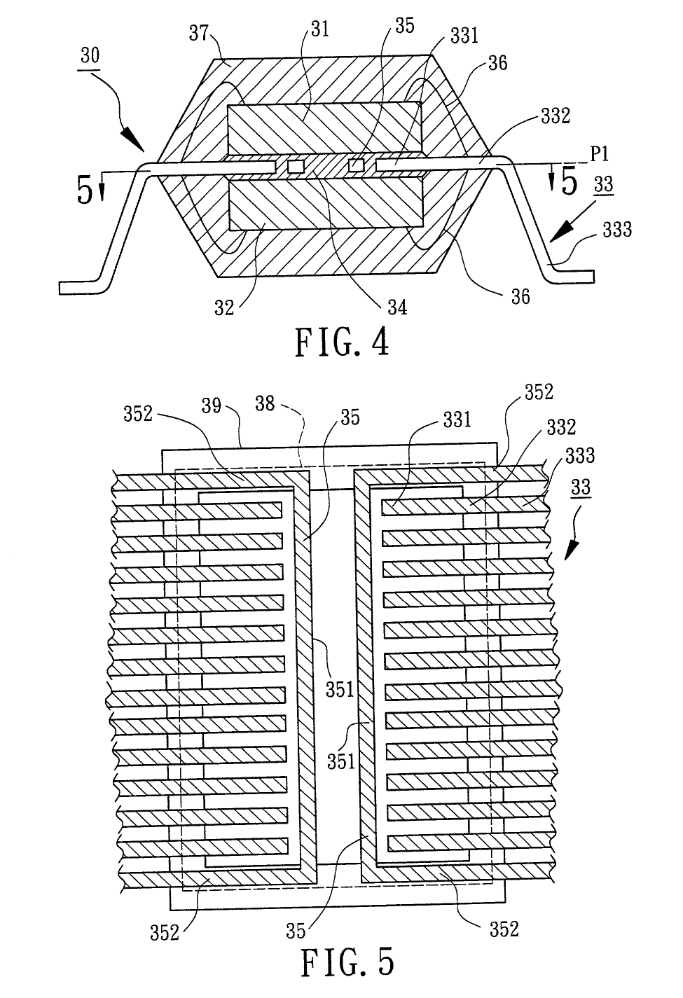

What is claimed is:

1. A double sided chip package comprising:
a LOC lead frame having a plurality of leads, wherein each lead being from inside to outside divided into a supporting portion, an inner connecting portion and an outer connecting portion;
an upper chip having a plurality of bonding pads on its upper surface and being fixed to the top of the supporting portions of the leads with its bottom surface;
a bottom chip having a plurality of bonding pads and being fixed to the bottom of the supporting portions of the leads with its top surface;
a plurality of bonding wires electrically connecting the bonding pads of the upper chip to the inner connecting portions of the corresponding leads, and the bonding pads of the bottom chip to the inner connecting portions of the corresponding leads, respectively; and
a package body sealing the upper chip, the bottom chip, the bonding wires, the supporting portions and the inner connecting portions of the leads.

2. The double sided chip package in accordance with claim 1, further comprising a plurality of tapes fixing the upper chip and the bottom chip to the supporting portions of the leads.

3. The double sided chip package in accordance with claim 1, further comprising a epoxy compound fixing the upper chip and bottom chip on the supporting portions of the leads.

4. The double sided chip package in accordance with claim 1, wherein the supporting portions and the inner connecting portions of a plurality of leads are formed on the same plane.

5. The double sided chip package in accordance with claim 4, wherein the supporting portions and the inner connecting portions of a plurality of leads are formed on the same plane with equal distance to the upper chip and the bottom chip.

6. The double sided chip package in accordance with claim 1, wherein the LOC lead frame additionally includes at least a power lead comprising a supporting portion sandwiched between the upper chip and the bottom chip, and is perpendicular to the supporting portions of the other leads.
